(19) United States
(12) Patent Application Publication
(10) Pub. No.: US 2018/0254223 A1
(43) Pub. Date: Sep. 6, 2018

(54) SEMICONDUCTOR INGOT INSPECTING METHOD AND APPARATUS, AND LASER PROCESSING APPARATUS

(71) Applicant: DISCO CORPORATION, Tokyo (JP)

(72) Inventors: Kazuya Hirata, Tokyo (JP); Ryohei Yamamoto, Tokyo (JP); Kunimitsu Takahashi, Tokyo (JP)

(21) Appl. No.: 15/908,307

(22) Filed: Feb. 28, 2018

(30) Foreign Application Priority Data
Mar. 1, 2017 (JP) 2017-038435

(51) Int. Cl. H01L 21/66; H01L 21/02; H01L 21/268

(52) U.S. Cl. CPC H01L 22/12; H01L 21/2686; H01L 21/0201

(57) ABSTRACT

Disclosed herein is an inspecting method for a semiconductor ingot in which modified layers parallel to an upper surface of the ingot and cracks extending from each modified layer are previously formed as a separation start point. The inspecting method includes a light applying step of applying light from a light source to the upper surface of the ingot, the light impinging on the upper surface at a predetermined incidence angle, a projected image forming step of reflecting the light on the upper surface of the ingot to obtain reflected light and then forming a projected image from the reflected light, the projected image showing the emphasis of asperities generated on the upper surface of the ingot due to the formation of the modified layers and the cracks inside the ingot, an imaging step of detecting the projected image to form a detected image, and a determining step of comparing the detected image with preset conditions to determine the condition of the modified layers and the cracks.

### BACKGROUND OF THE INVENTION

### Field of the Invention

The present invention relates to a semiconductor ingot inspecting method, a semiconductor ingot inspecting apparatus, and a laser processing apparatus.

### Description of the Related Art

Various devices such as integrated circuits (ICs) and large-scale integrations (LSIs) are formed by forming a functional layer on the front side of a wafer formed of silicon or the like and partitioning this functional layer into a plurality of regions along a plurality of crossing division lines. The division lines of the wafer are processed by a processing apparatus such as a cutting apparatus and a laser processing apparatus to thereby divide the wafer into a plurality of individual device chips corresponding to the devices. The device chips thus obtained are widely used in various electronic equipment such as mobile phones and personal computers. Further, power devices or optical devices such as light emitting diodes (LEDs) and laser diodes (LDs) are formed by forming a functional layer on the front side of a wafer formed of a hexagonal single crystal such as SiC and GaN and partitioning this functional layer into a plurality of regions along a plurality of crossing division lines.

In general, the wafer on which the devices are to be formed is produced by slicing an ingot with a wire saw. Both sides of the wafer obtained above are polished to a mirror finish (see Japanese Patent Laid-Open No. 2000-94221, for example). This wire saw is configured in such a manner that a single wire such as a piano wire having a diameter of approximately 100 to 300 μm is wound around many grooves formed on usually two to four guide rollers to form a plurality of cutting portions spaced in parallel with a given pitch. The wire is operated to run in one direction or opposite directions, thereby slicing the ingot into a plurality of wafers.

However, when the ingot is cut by the wire saw and both sides of each wafer are polished to obtain the product, 70% to 80% of the ingot is discarded to cause a problem of poor economy. In particular, a hexagonal single crystal ingot of SiC or GaN, for example, has high Mohs hardness and it is therefore difficult to cut this ingot with the wire saw. Accordingly, considerable time is required for cutting of the ingot, causing a reduction in productivity. That is, there is a problem in efficiently producing a wafer in this prior art.

A technique for solving this problem is described in Japanese Patent Laid-Open No. 2013-49161. This technique includes the steps of setting the focal point of a laser beam having a transmission wavelength to SiC inside a hexagonal single crystal ingot, next applying the laser beam to the ingot as scanning the laser beam on the ingot to thereby form modified layers and cracks in a separation plane inside the ingot, and next applying an external force to the ingot to thereby break the ingot along the separation plane where the modified layers and the cracks are formed, thus separating a wafer from the ingot.

In this technique, the laser beam (pulsed laser beam) is scanned spirally or linearly along the separation plane so that a first application point of the laser beam and a second application point of the laser beam nearest to the first application point have a predetermined positional relation with each other. As a result, the modified layers and the cracks are formed at very high density in the separation plane of the ingot. However, in the ingot cutting method described in Japanese Patent Laid-Open No. 2013-49161 mentioned above, the laser beam is scanned spirally or linearly on the ingot. In the case of linearly scanning the laser beam, the direction of scanning of the laser beam is not specified.

In this ingot cutting method, the pitch (spacing) between the first application point and the second application point of the laser beam as mentioned above is set to 1 to 10 μm. In this manner, the pitch of the application points of the laser beam to be applied to the ingot is very small. Accordingly, the laser beam must be applied with a very small pitch, and the improvement in productivity is not yet sufficient. To solve this problem, the present applicant has proposed a wafer producing method which can efficiently produce a wafer from a hexagonal single crystal ingot as described in Japanese Patent Laid-Open No. 2016-111143, for example.

### SUMMARY OF THE INVENTION

According to the wafer producing method described in Japanese Patent Laid-Open No. 2016-111143, a separation start point composed of modified layers and cracks can be efficiently formed inside the hexagonal single crystal ingot by applying a laser beam to the ingot. However, since the separation start point is formed inside the ingot, it is difficult to detect whether or not the separation start point has been properly formed, from the outside of the ingot before separating a wafer from the ingot.

It is therefore an object of the present invention to provide a semiconductor ingot inspecting method which can determine whether or not a separation start point composed of modified layers and cracks has been properly formed inside a semiconductor ingot.

It is another object of the present invention to provide a semiconductor ingot inspecting apparatus for performing the above semiconductor ingot inspecting method.

It is a further object of the present invention to provide a laser processing apparatus including the above semiconductor ingot inspecting apparatus.

In accordance with an aspect of the present invention, there is provided a semiconductor ingot inspecting method including a separation start point forming step of setting the focal point of a laser beam having a transmission wavelength to a semiconductor ingot inside the ingot at a predetermined depth from an upper surface of the ingot, the predetermined depth corresponding to the thickness of a wafer to be produced from the ingot, and next applying the laser beam to the upper surface of the ingot as relatively moving the focal point and the ingot to thereby form modified layers parallel to the upper surface of the ingot and cracks extending from each modified layer, thus forming a separation start point composed of the modified layers and the cracks; a light applying step of applying light from a light source to the upper surface of the ingot after performing the separation start point forming step, the light impinging on the upper surface of the ingot at a predetermined incidence angle; a projected image forming step of reflecting the light on the upper surface of the ingot to obtain reflected light after performing the light applying step, and then forming a projected image from the reflected light, the projected image showing the emphasis of asperities generated on the upper surface of the ingot due to the formation of the modified layers and the cracks inside the ingot; an imaging step of detecting the projected image to form a detected image after performing the projected image forming step; and a determining step of comparing the detected image with preset conditions to determine the condition of the modified layers and the cracks after performing the imaging step.

In accordance with another aspect of the present invention, there is provided a hexagonal single crystal ingot inspecting method including a preparing step of preparing a hexagonal single crystal ingot having a first surface, a second surface opposite to the first surface, a c-axis extending from the first surface to the second surface, and a c-plane perpendicular to the c-axis; a separation start point forming step of setting the focal point of a laser beam having a transmission wavelength to the ingot inside the ingot at a predetermined depth from the first surface of the ingot after performing the preparing step, the predetermined depth corresponding to the thickness of a wafer to be produced from the ingot, and next applying the laser beam to the first surface of the ingot as relatively moving the focal point and the ingot to thereby form modified layers parallel to the first surface of the ingot and cracks extending from each modified layer along the c-plane, thus forming a separation start point composed of the modified layers and the cracks; a light applying step of applying light from a light source to the first surface of the ingot after performing the separation start point forming step, the light impinging on the first surface of the ingot at a predetermined incidence angle; a projected image forming step of reflecting the light on the first surface of the ingot to obtain reflected light after performing the light applying step, and then forming a projected image from the reflected light, the projected image showing the emphasis of asperities generated on the first surface of the ingot due to the formation of the modified layers and the cracks inside the ingot; an imaging step of detecting the projected image to form a detected image after performing the projected image forming step; and a determining step of comparing the detected image with preset conditions to determine the condition of the modified layers and the cracks after performing the imaging step.

Preferably, the hexagonal single crystal ingot is selected from an SiC single crystal ingot and a GaN single crystal ingot.

In accordance with a further aspect of the present invention, there is provided an inspecting apparatus for inspecting a hexagonal single crystal ingot having a first surface, a second surface opposite to the first surface, a c-axis extending from the first surface to the second surface, and a c-plane perpendicular to the c-axis, the ingot being previously processed by applying a laser beam having a transmission wavelength to the ingot, to the first surface of the ingot to thereby form modified layers inside the ingot and cracks extending from each modified layer along the c-plane, thus forming a separation start point composed of the modified layers and the cracks, whereby asperities corresponding to the modified layers and the cracks are generated on the first surface of the ingot, the inspecting apparatus including a holding table for holding the ingot in the condition where the first surface of the ingot is exposed; a light source for applying light to the first surface of the ingot held on the holding table, the light impinging on the first surface of the ingot at a predetermined incidence angle; imaging means for detecting a projected image to form a detected image, the projected image being formed by reflecting the light on the first surface of the ingot at a reflection angle corresponding to the predetermined incidence angle, the projected image showing the emphasis of the asperities generated on the first surface of the ingot due to the formation of the separation start point inside the ingot; and determining means for comparing the detected image with preset conditions to determine the condition of the modified layers and the cracks. Preferably, the inspecting apparatus further includes a screen for forming the projected image, in which the screen is provided by a concave surface of a concave mirror.

In accordance with a still further aspect of the present invention, there is provided an inspecting apparatus for inspecting a hexagonal single crystal ingot having a first surface, a second surface opposite to the first surface, a c-axis extending from the first surface to the second surface, and a c-plane perpendicular to the c-axis, the ingot being previously processed by applying a laser beam having a transmission wavelength to the ingot, to the first surface of the ingot to thereby form modified layers inside the ingot and cracks extending from each modified layer along the c-plane, thus forming a separation start point composed of the modified layers and the cracks, whereby asperities corresponding to the modified layers and the cracks are generated on the first surface of the ingot, the inspecting apparatus including a holding table for holding the ingot in the condition where the first surface of the ingot is exposed; a point light source for emitting light; a first concave mirror for reflecting the light emitted from the point light source to convert the light into parallel light and then applying the parallel light to the first surface of the ingot, the parallel light impinging on the first surface of the ingot at a predetermined incidence angle; a second concave mirror having a projection surface for forming a projected image, the projected image being formed by reflecting the parallel light on the first surface of the ingot at a reflection angle corresponding to the predetermined incidence angle, the projected image showing the emphasis of the asperities generated on the first surface of the ingot due to the formation of the separation start point inside the ingot; imaging means for detecting the projected image formed on the projection surface of the second concave mirror to thereby form a detected image; and determining means for comparing the detected image with preset conditions to determine the condition of the modified layers and the cracks.

In accordance with a still further aspect of the present invention, there is provided a laser processing apparatus including a chuck table for holding a hexagonal single crystal ingot having a first surface, a second surface opposite to the first surface, a c-axis extending from the first surface to the second surface, and a c-plane perpendicular to the c-axis; laser beam applying means for applying a laser beam having a transmission wavelength to the ingot, to the first surface of the ingot held on the chuck table to thereby form modified layers inside the ingot and cracks extending from each modified layer along the c-plane, thus forming a separation start point composed of the modified layers and the cracks, whereby asperities corresponding to the modified layers and the cracks are generated on the first surface of the ingot; a light source for applying light to the first surface of the ingot held on the chuck table, the light impinging on the first surface of the ingot at a predetermined incidence angle; imaging means for detecting a projected image to form a detected image, the projected image being formed by reflecting the light on the first surface of the ingot at a reflection angle corresponding to the predetermined incidence angle, the projected image showing the emphasis of the asperities generated on the first surface of the ingot due to the formation of the separation start point inside the ingot; determining means for comparing the detected image with preset conditions to determine the condition of the modified layers and the cracks; and control means for essentially controlling the laser beam applying means, the imaging means, and the determining means.

According to the present invention, the light emitted from the light source is applied to the upper surface (first surface) of the semiconductor ingot or the hexagonal single crystal ingot at a predetermined incidence angle (also including 0 degrees, i.e., the optical path of the incident light is parallel to the normal to the upper surface). The light applied to the upper surface of the ingot is reflected to be projected onto the screen. As a result, a projected image is formed on the screen from the reflected light, in which the projected image shows the emphasis of asperities generated on the upper surface of the ingot due to the formation of the separation start point inside the ingot. Accordingly, by detecting this projected image, the condition of the separation start point composed of the modified layers and the cracks can be easily determined. That is, it can be easily determined whether or not the modified layers and the cracks have been properly formed inside the ingot.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a laser processing apparatus suitable for use in performing the inspecting method of the present invention;

FIG. 2 is a block diagram of a laser beam generating unit;

FIG. 3A is a perspective view of a hexagonal single crystal ingot;

FIG. 3B is an elevational view of the ingot shown in FIG. 3A;

FIG. 4 is a perspective view for illustrating a separation start point forming step;

FIG. 5 is a plan view of the ingot shown in FIG. 3A;

FIG. 6 is a schematic sectional view for illustrating a modified layer forming step;

FIG. 7 is a schematic plan view for illustrating the modified layer forming step;

FIG. 8 is a schematic illustration of an inspecting apparatus according to a preferred embodiment of the present invention;

FIG. 9 is a schematic illustration of an inspecting apparatus according to another preferred embodiment of the present invention;

FIG. 10 is a schematic illustration of an inspecting apparatus according to still another preferred embodiment of the present invention;

FIG. 11 is a plan view showing a projected image in the case that modified layers have been properly formed inside the ingot; and

FIG. 12 is a plan view showing a projected image in the case that modified layers have not been properly formed inside the ingot.

### DETAILED DESCRIPTION OF THE PREFERRED EMBODIMENTS

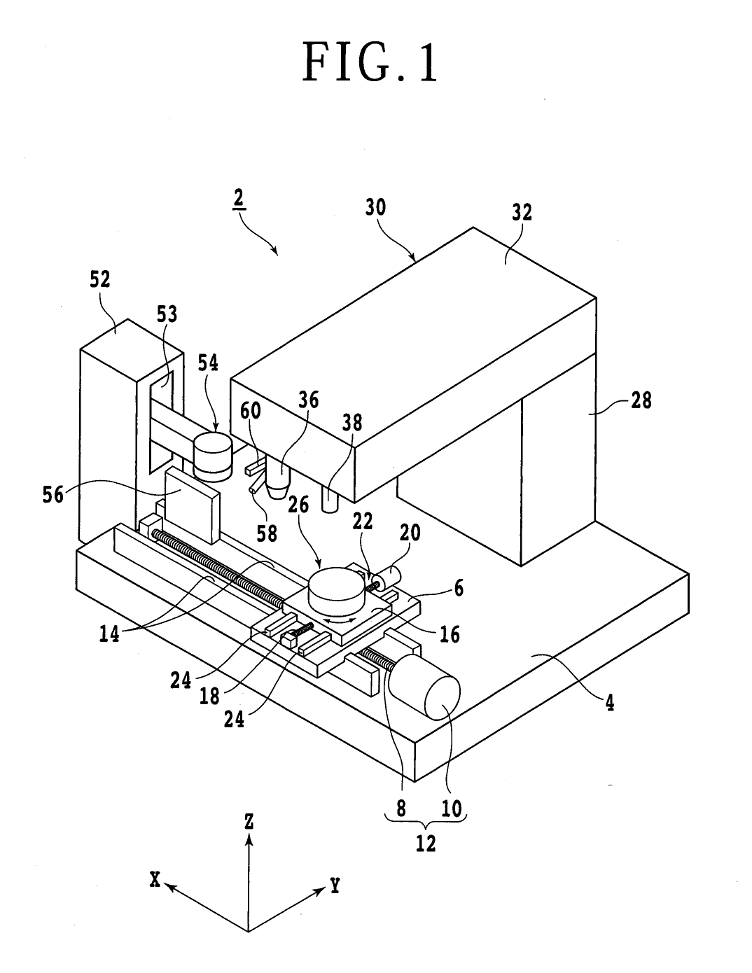

Preferred embodiments of the present invention will now be described in detail with reference to the drawings. Referring to FIG. 1, there is shown a perspective view of a laser processing apparatus 2 suitable for use in performing the inspecting method of the present invention. The laser processing apparatus 2 includes a stationary base 4 and a first slide block 6 mounted on the stationary base 4 so as to be movable in the X direction. The first slide block 6 is moved in a feeding direction, or in the X direction along a pair of guide rails 14 by a feeding mechanism 12 composed of a ball screw 8 and a pulse motor 10.

A second slide block 16 is mounted on the first slide block 6 so as to be movable in the Y direction. The second slide block 16 is moved in an indexing direction, or in the Y direction along a pair of guide rails 24 by an indexing mechanism 22 composed of a ball screw 18 and a pulse motor 20. A support table (holding table or chuck table) 26 is mounted on the second slide block 16. The support table 26 is movable in the X direction and the Y direction by the feeding mechanism 12 and the indexing mechanism 22 and also rotatable by a motor stored in the second slide block 16.

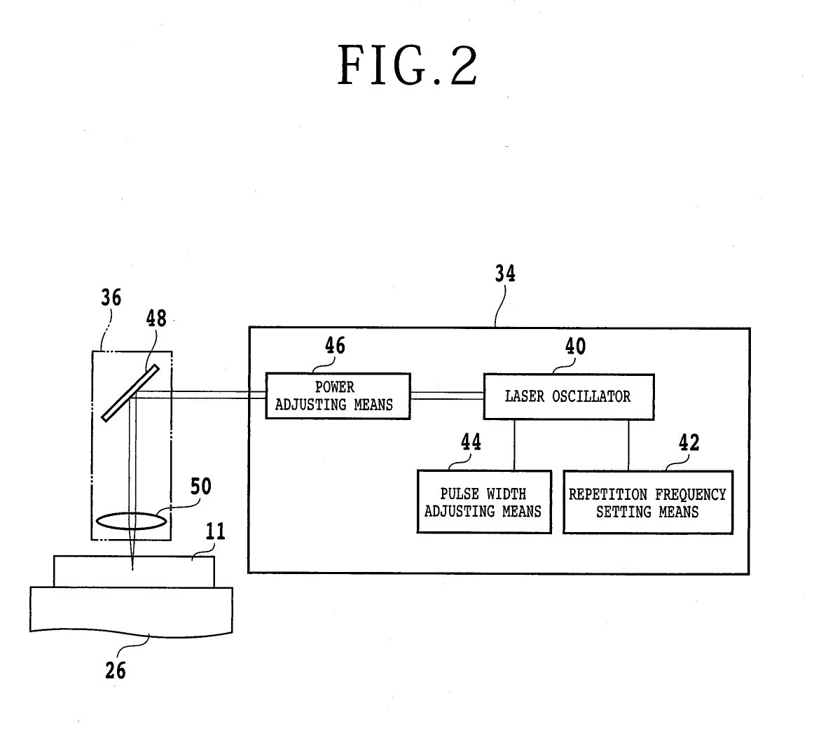

A column 28 is provided on the stationary base 4 so as to project upward therefrom. A laser beam applying mechanism (laser beam applying means) 30 is mounted on the column 28. The laser beam applying mechanism 30 is composed of a casing 32, a laser beam generating unit 34 (see FIG. 2) stored in the casing 32, and focusing means (laser head) 36 mounted on the front end of the casing 32. An imaging unit 38 having a microscope and a camera is also mounted on the front end of the casing 32 so as to be aligned with the focusing means 36 in the X direction.

As shown in FIG. 2, the laser beam generating unit 34 includes a laser oscillator 40 such as YAG laser and YVO4 laser for generating a pulsed laser beam, repetition frequency setting means 42 for setting the repetition frequency of the pulsed laser beam to be generated by the laser oscillator 40, pulse width adjusting means 44 for adjusting the pulse width of the pulsed laser beam to be generated by the laser oscillator 40, and power adjusting means 46 for adjusting the power of the pulsed laser beam generated by the laser oscillator 40. Although especially not shown, the laser oscillator 40 has a Brewster window, so that the laser beam generated from the laser oscillator 40 is a laser beam of linearly polarized light. After the power of the pulsed laser beam is adjusted to a predetermined power by the power adjusting means 46 of the laser beam generating unit 34, the pulsed laser beam is reflected by a mirror 48 included in the focusing means 36 and next focused by a focusing lens 50 included in the focusing means 36. The focusing lens 50 is positioned so that the pulsed laser beam is focused inside a hexagonal single crystal ingot 11 as a workpiece fixed to the support table 26.

There will now be described a workpiece particularly suitable in performing the inspecting method of the present invention. The inspecting method of the present invention is especially applicable to the case of inspecting whether or not a separation start point has been properly formed inside a hexagonal single crystal ingot, in which the separation start point is composed of modified layers and cracks formed inside the ingot by applying a laser beam to the ingot. However, the inspecting method of the present invention is also applicable to the case of inspecting whether or not such a separation start point has been formed inside a semiconductor ingot such as a silicon ingot and a compound semiconductor ingot.

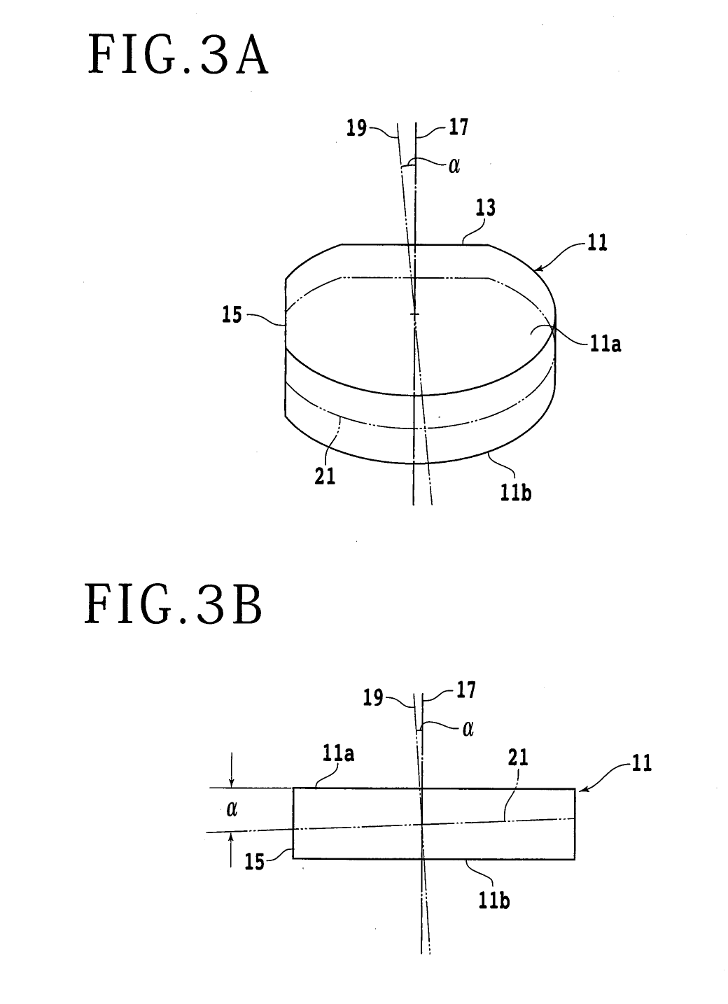

Referring to FIG. 3A, there is shown a perspective view of the hexagonal single crystal ingot 11 as a workpiece to be processed. FIG. 3B is an elevational view of the hexagonal single crystal ingot 11 shown in FIG. 3A. The hexagonal single crystal ingot (which will be hereinafter referred to also simply as ingot) 11 is selected from an SiC single crystal ingot and a GaN single crystal ingot. The ingot 11 has a first surface (upper surface) 11a and a second surface (lower surface) 11b opposite to the first surface 11a. The first surface 11a of the ingot 11 is previously polished to a mirror finish because the laser beam is applied to the first surface 11a.

The ingot 11 has a first orientation flat 13 and a second orientation flat 15 perpendicular to the first orientation flat 13. The length of the first orientation flat 13 is set longer than the length of the second orientation flat 15. The ingot 11 has a c-axis 19 inclined by an off angle α toward the second orientation flat 15 with respect to a normal 17 to the upper surface 11a and also has a c-plane 21 perpendicular to the c-axis 19. The c-plane 21 is inclined by the off angle α with respect to the upper surface 11a. In general, in the hexagonal single crystal ingot 11, the direction perpendicular to the direction of extension of the shorter second orientation flat 15 is the direction of inclination of the c-axis.

The c-plane 21 is set in the ingot 11 innumerably at the molecular level of the ingot 11. In this preferred embodiment, the off angle α is set to 4 degrees. However, the off angle α is not limited to 4 degrees in the present invention. For example, the off angle α may be freely set in the range of 1 to 6 degrees in manufacturing the ingot 11.

Referring again to FIG. 1, a column 52 is fixed to the left side of the stationary base 4. The column 52 is formed with a vertically elongated opening 53, and a pressing mechanism 54 for separating a wafer from the ingot 11 is vertically movably mounted to the column 52 so as to project from the opening 53.

A light source 58 for applying light to the whole of the ingot 11 supported on the support table 26 is provided near the focusing means 36 in a working position where the support table 26 supporting the ingot 11 thereon is set below the focusing means 36. That is, the light source 58 is set at the working position near the column 52. Examples of the light source 58 includes an incandescent lamp and an LED. However, the light source 58 is not limited in kind, position, etc. Further, the light to be applied to the ingot 11 may be parallel light (collimated beam) or nonparallel light. In the case that the light to be applied to the ingot 11 is parallel light, the light emitted from the light source 58 may be converted into parallel light by using an optical component such as a lens and a concave mirror. Preferably, a point light source having a small light emission area is used as the light source 58.

Further, a screen 56 is provided above the support table 26 set in the working position near the column 52. The screen 26 is provided, so as to form a projected image by receiving reflected light from the upper surface 11a of the ingot 11 supported on the support table 26, in which the reflected light is obtained by the reflection of the light applied from the light source 58 to the upper surface 11a of the ingot 11. The screen 56 may be arranged in any condition, provided that the whole of the ingot 11 can be projected onto the screen 56. Further, an imaging unit (imaging means) 60 is provided so as to be opposed to the screen 56. This imaging unit 60 functions to detect the projected image formed on the screen 56, thereby forming a detected image. This imaging unit 60 is a digital camera configured by combining an imaging device such as charge-coupled device (CCD) and complementary metal oxide semiconductor (CMOS) and an optical element such as lens. The imaging unit 60 outputs the detected image formed by detecting the projected image to any external equipment.

The imaging unit 60 may be selected from a digital still camera for forming a still image and a digital video camera for forming a video image. Although not shown in FIG. 1, a determining unit (determining means) is connected to the imaging unit 60. The determining unit functions to compare the detected image output from the imaging unit 60 with preset conditions and then determine the condition of the separation start point composed of the modified layers and the cracks formed inside the ingot 11.

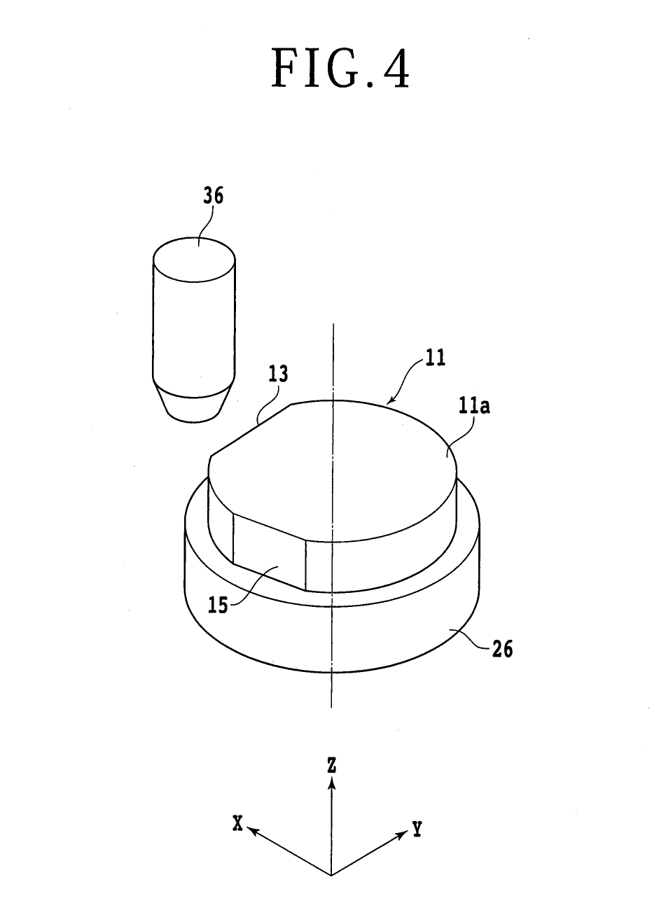

There will now be described with reference to FIGS. 4 to 7 a method of forming the separation start point composed of the modified layers and the cracks inside the ingot 11 by applying a laser beam to the ingot 11, the laser beam having a transmission wavelength to the ingot 11. As shown in FIG. 4, the ingot 11 is fixed to the upper surface of the support table 26 by using a wax or adhesive in the condition where the second orientation flat 15 of the ingot 11 becomes parallel to the X direction.

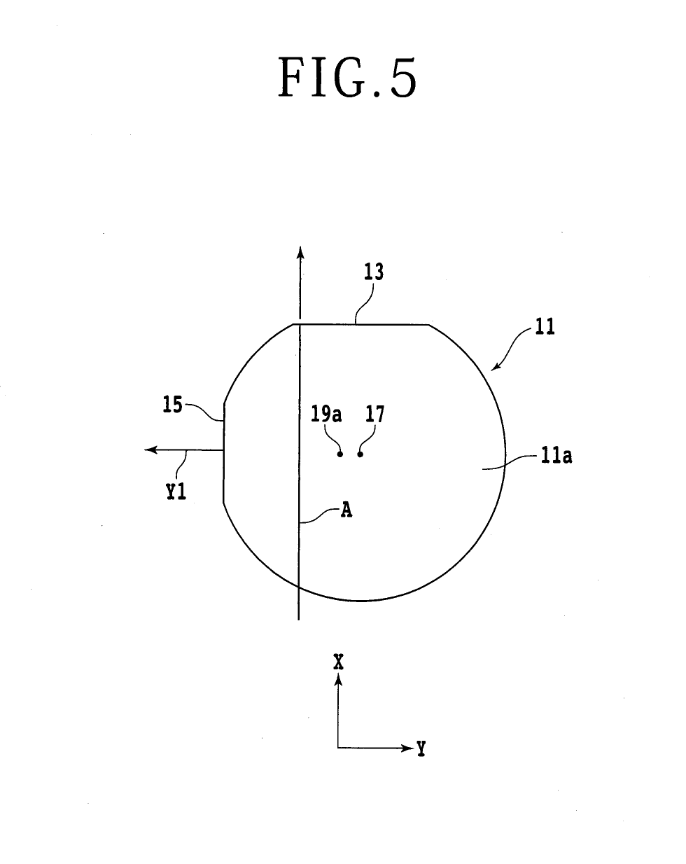

In other words, as shown in FIG. 5, the direction of formation of the off angle α is shown by an arrow Y1. That is, the direction of the arrow Y1 is the direction where the intersection 19a between the c-axis 19 and the upper surface 11a of the ingot 11 is present with respect to the normal 17 to the upper surface 11a. Further, the direction perpendicular to the direction of the arrow Y1 is shown by an arrow A. Then, the ingot 11 is fixed to the support table 26 in the condition where the direction of the arrow A becomes parallel to the X direction. Accordingly, the laser beam is scanned in the direction of the arrow A perpendicular to the direction of the arrow Y1, or the direction of formation of the off angle α. In other words, the direction of the arrow A perpendicular to the direction of the arrow Y1 where the off angle α is formed is defined as the feeding direction of the support table 26.

In properly forming the separation start point composed of the modified layers and the cracks inside the ingot 11, it is important that the scanning direction of the laser beam to be applied from the focusing means 36 is set to the direction of the arrow A perpendicular to the direction of the arrow Y1 where the off angle α of the ingot 11 is formed. That is, by setting the scanning direction of the laser beam to the direction of the arrow A as mentioned above, the cracks propagating from each modified layer formed inside the ingot 11 by the laser beam extend very long along the c-plane 21.

In this preferred embodiment, a separation start point forming step is first performed in such a manner that the focal point of the laser beam having a transmission wavelength (e.g., 1064 nm) to the hexagonal single crystal ingot 11 fixed to the support table 26 is set inside the ingot 11 at a predetermined depth from the first surface (upper surface) 11a, the predetermined depth corresponding to the thickness of a wafer to be produced, and the laser beam is next applied to the upper surface 11a as relatively moving the focal point and the ingot 11 to thereby form a plurality of modified layers 23 parallel to the upper surface 11a and cracks 25 propagating from each modified layer 23 along the c-plane 21, thus forming the separation start point composed of the modified layers 23 and the cracks 25 inside the ingot 11.

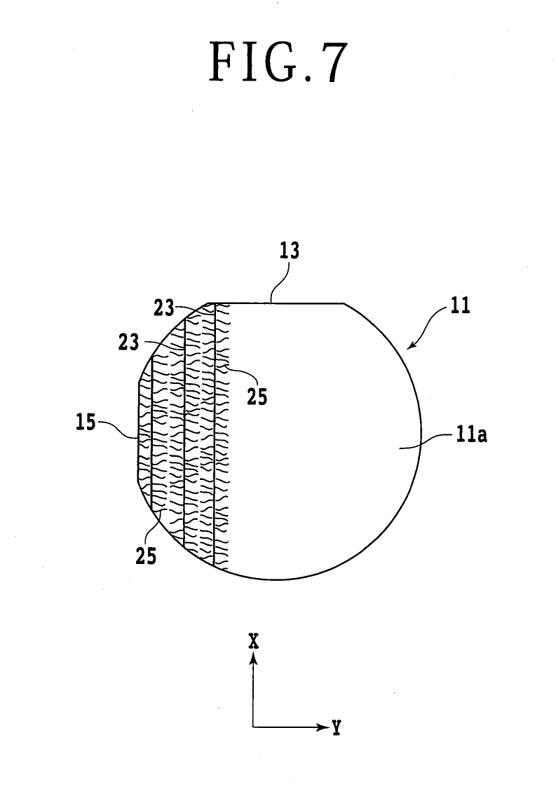

This separation start point forming step includes a modified layer forming step of relatively moving the focal point of the laser beam in the direction of the arrow A (i.e., in the X direction) perpendicular to the direction of the arrow Y1 where the c-axis 19 is inclined by the off angle α with respect to the normal 17 to the upper surface 11a and the off angle α is formed between the c-plane 21 and the upper surface 11a, thereby forming the modified layer 23 inside the ingot 11 along a line extending in the X direction and the cracks 25 propagating from the modified layer 23 along the c-plane 21, and also includes an indexing step of relatively moving the focal point in the direction of formation of the off angle α, i.e., in the Y direction to thereby index the focal point by a predetermined amount as shown in FIG. 7.

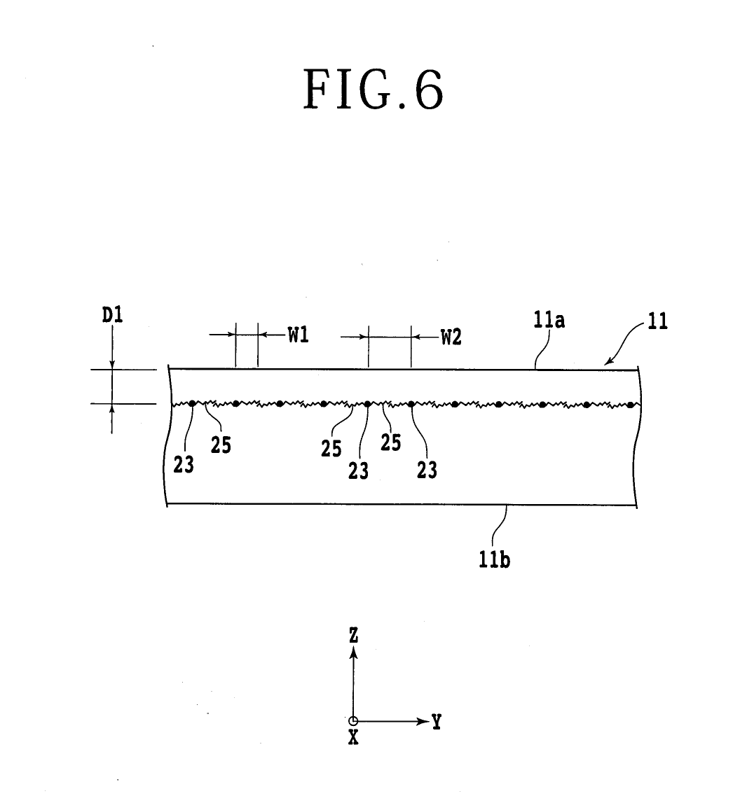

As shown in FIGS. 6 and 7, each modified layer 23 is linearly formed so as to extend in the X direction, so that the cracks 25 propagate from each modified layer 23 in opposite directions along the c-plane 21. In this preferred embodiment, the separation start point forming step further includes an index amount setting step of measuring the width of the cracks 25 formed on one side of each modified layer 23 along the c-plane 21 and then setting the index amount of the focal point according to the width measured above. More specifically, as shown in FIG. 6, letting W1 denote the width of the cracks 25 formed on one side of each modified layer 23 so as to propagate from each modified layer 23 along the c-plane 21, the index amount W2 of the focal point is set in the range of W1 to 2W1.

For example, the separation start point forming step is performed under the following laser processing conditions.

Light source: Nd:YAG pulsed laser

Wavelength: 1064 nm

Repetition frequency: 80 kHz

Average power: 3.2 W

Pulse width: 4 ns

Spot diameter: 10 μm

Numerical aperture (NA) of the focusing lens: 0.45

Index amount: 400 μm

In the laser processing conditions mentioned above, the width W1 of the cracks 25 propagating from each modified layer 23 along the c-plane 21 in one direction as viewed in FIG. 6 is set to approximately 250 μm, and the index amount W2 is set to 400 μm. However, the average power of the laser beam is not limited to 3.2 W. When the average power of the laser beam was set to 2 to 4.5 W, good results were obtained in the preferred embodiment. In the case that the average power was set to 2 W, the width W1 of the cracks 25 was approximately 100 μm. In the case that the average power was set to 4.5 W, the width W1 of the cracks 25 was approximately 350 μm.

In the case that the average power is less than 2 W or greater than 4.5 W, the modified layers 23 cannot be well formed inside the ingot 11. Accordingly, the average power of the laser beam to be applied is preferably set in the range of 2 to 4.5 W. For example, the average power of the laser beam to be applied to the ingot 11 was set to 3.2 W in this preferred embodiment. As shown in FIG. 6, the depth D1 of the focal point from the upper surface 11a in forming the modified layers 23 was set to 500 μm.

In this manner, the focal point of the laser beam is sequentially indexed to form the plural modified layers 23 at the depth D1 in the whole area of the ingot 11 and the cracks 25 extending from each modified layer 23 along the c-plane 21, thereby forming the separation start point inside the ingot 11. Thus, the separation start point composed of the modified layers 23 and the cracks 25 is formed inside the ingot 11, so that it is difficult to visually check whether or not this separation start point has been properly formed.

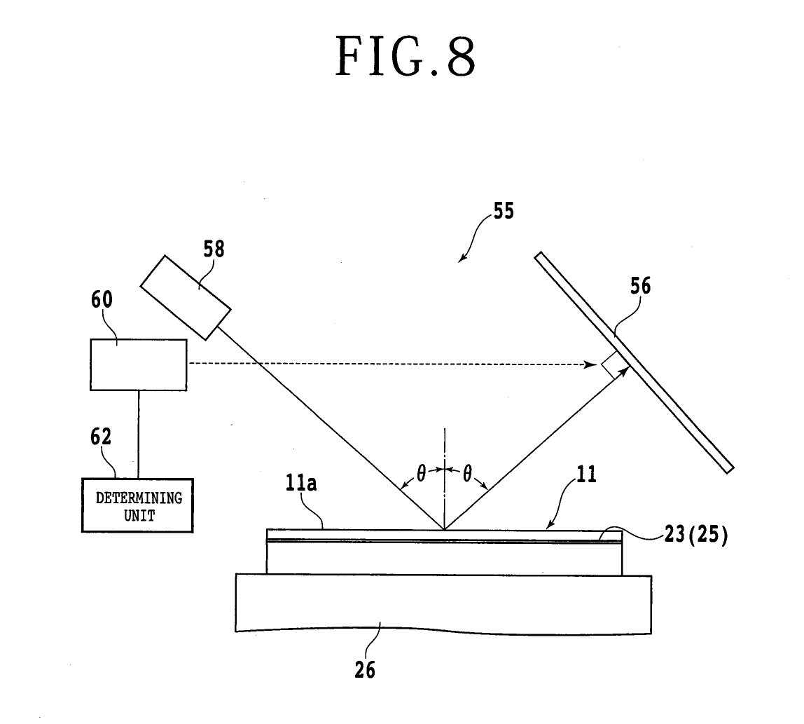

The inspecting method of the present invention is a method of inspecting whether or not the separation start point has been properly formed inside the ingot 11. A preferred embodiment of the inspecting method of the present invention will now be described in detail with reference to FIGS. 8 to 12. The inspecting method of the present invention is based on the principle of magic mirror. The upper surface 11a of the ingot 11 is a mirror surface. That is, before applying the laser beam to the ingot 11 to form the modified layers 23 inside the ingot 11, the upper surface 11a of the ingot 11 is a flat surface.

However, by applying the laser beam to the ingot 11 to form the modified layers 23 inside the ingot 11 in the above separation start point forming step, the ingot 11 is expanded in the vicinity of the focal point of the laser beam, so that minute projections that cannot be visually recognized are formed on the upper surface 11a at positions corresponding to the modified layers 23. That is, a minute projection is formed on the upper surface 11a with the same timing as that of formation of each modified layer 23 inside the ingot 11. Further, the cracks 25 are formed as microscopic projections having a submicron size smaller than that of each modified layer 23, so that the influence of the cracks 25 upon the condition of the upper surface 11a is little. However, there is a case that the cracks generated in a region continuous to each modified layer cause a slight projection on the upper surface 11a.

The inspecting method of the present invention includes the steps of applying light to the upper surface 11a of the ingot 11 perpendicularly or obliquely to the upper surface 11a (light applying step), next forming a projected image as the emphasis of asperities generated on the upper surface 11a of the ingot 11 due to the formation of the separation start point inside the ingot 11 (projected image forming step), next detecting this projected image to form a detected image by using the imaging unit 60 (imaging step), and finally determining whether or not the modified layers 23 have been properly formed inside the ingot 11 according to this detected image (determining step).

Referring to FIG. 8, there is shown a schematic illustration of an inspecting apparatus 55 according to a preferred embodiment. The inspecting apparatus 55 includes a light source 58 for applying light to the upper surface 11a of the ingot 11 fixed to the support table 26, the light impinging on the upper surface 11a at a predetermined incidence angle θ, the modified layers 23 and the cracks 25 being previously formed as the separation start point inside the ingot 11. The inspecting apparatus 55 further includes a screen 56 for receiving reflected light from the upper surface 11a of the ingot 11 to form a projected image, the reflected light being obtained by the reflection of the light applied from the light source 58 to the upper surface 11a, the projected image being formed on the screen 56 so as to emphasize the asperities generated on the upper surface 11a. The inspecting apparatus 55 further includes an imaging unit 60 for detecting the projected image formed on the screen 56 to thereby form a detected image and a determining unit 62 for comparing the detected image with preset conditions and then determining whether or not the modified layers 23 and the cracks 25 have been properly formed inside the ingot 11.

While the ingot 11 is fixed through a wax or adhesive to the support table 26 in this preferred embodiment, the support table 26 may be replaced by a chuck table having a suction holding portion as frequently used in a laser processing apparatus, in which the ingot 11 is held on the suction holding portion of the chuck table under suction.

In performing the inspecting method by using the inspecting apparatus 55, the support table 26 holding the ingot 11 in which the modified layers 23 and the cracks 25 are previously formed as the separation start point is moved in the X direction by operating the feeding mechanism 12 until reaching the area where the screen 56, the light source 58, and the imaging unit 60 are provided. While the screen 56 is located substantially above the ball screw 8 as in FIG. 1, the screen 56 may be located so that the projected image can be easily formed from the reflected light obtained by the reflection of the light applied from the light source 58 to the upper surface 11a.

As shown in FIG. 8, the screen 56 is arranged so that its projected surface is perpendicular to the optical path of the reflected light from the surface 11a of the ingot 11. With this arrangement, a projected image with no distortion can be formed on the screen 56. Furthermore, by using a camera capable of correcting distortion by adjusting a depth of field, the projected image with no distortion can be detected.

After setting the support table 26 supporting the ingot 11 in the area where the screen 56, the light source 58, and the imaging unit 60 are provided, light is applied from the light source 58 such as LED to the upper surface 11a of the ingot 11 in which the modified layers 23 and the cracks 25 are previously formed as the separation start point, the light impinging on the upper surface 11a at a predetermined incidence angle θ. The light applied is reflected on the upper surface 11a of the ingot 11 to obtain the reflected light, which is projected onto the screen 56, so that a projected image showing the condition of the upper surface 11a of the ingot 11 is formed on the screen 56. Preferably the incidence angle θ is set in the range of 0 to 60 degrees, more preferably, in the range of 0 to 30 degrees.

As described above, the formation of the separation start point composed of the modified layers 23 and the cracks 25 inside the ingot 11 causes the formation of minute projections corresponding to the modified layers 23 on the upper surface 11a of the ingot 11. Since the cracks 25 are microscopic, the upper surface 11a of the ingot 11 in the area corresponding to the cracks 25 is substantially flat. Accordingly, the light reflected on the upper surface 11a in the area corresponding to the modified layers 23 is scattered or diffused by the minute projections formed on the upper surface 11a, so that this reflected light is projected as a dark image onto the screen 56. On the other hand, the light reflected on the upper surface 11a in the other flat area at a reflection angle θ equal to the incidence angle θ is projected as a bright image onto the screen 56.

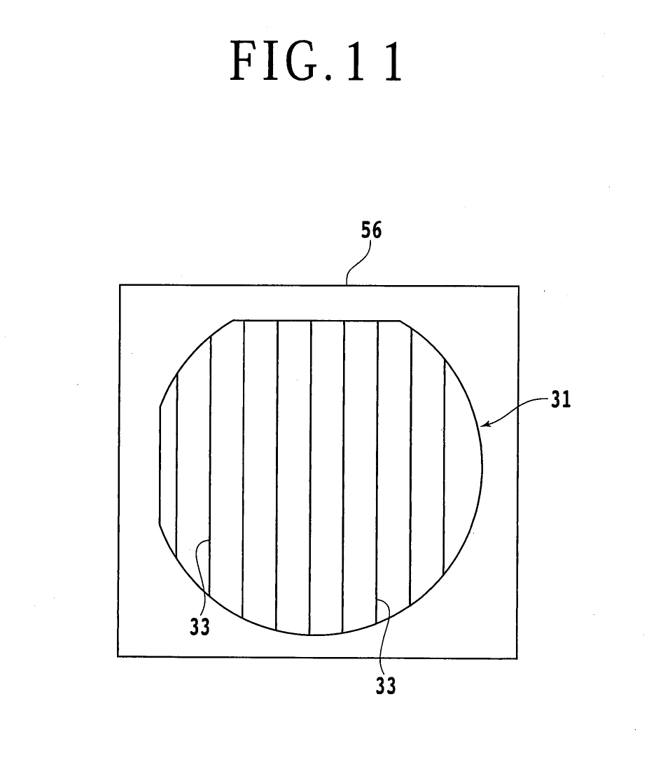

Accordingly, as shown in FIG. 11, the asperities generated on the upper surface 11a of the ingot 11 are emphasized to form a projected image 31 on the screen 56. In this projected image 31, the projections corresponding to the modified layers 23 are emphasized to form dark portions 33. This projected image 31 formed on the screen 56 is next detected by the imaging unit 60 such as a digital camera to form a detected image corresponding to this projected image 31. The detected image obtained by the imaging unit 60 is next transmitted to the determining unit 62.

A preset reference value, e.g., the width of each modified layer 23, is previously stored in the determining unit 62. The determining unit 62 detects the width of each dark portion 33 in the projected image 31 from the detected image by performing image processing or the like. Thereafter, the determining unit 62 compares the width of each dark portion 33 detected above with the preset reference value previously stored, thereby determining whether or not each modified layer 23 has been properly formed. More specifically, when the width of each dark portion 33 is greater than or equal to the reference value, the determining unit 62 determines that each modified layer 23 has been properly formed. Conversely, when the width of each dark portion 33 is less than the reference value, the determining unit 62 determines that each modified layer 23 has not been properly formed. In the projected image 31 shown in FIG. 11, the width of each dark portion 33 is greater than or equal to the reference value, so that the determining unit 62 determines that each modified layer 23 has been properly formed.

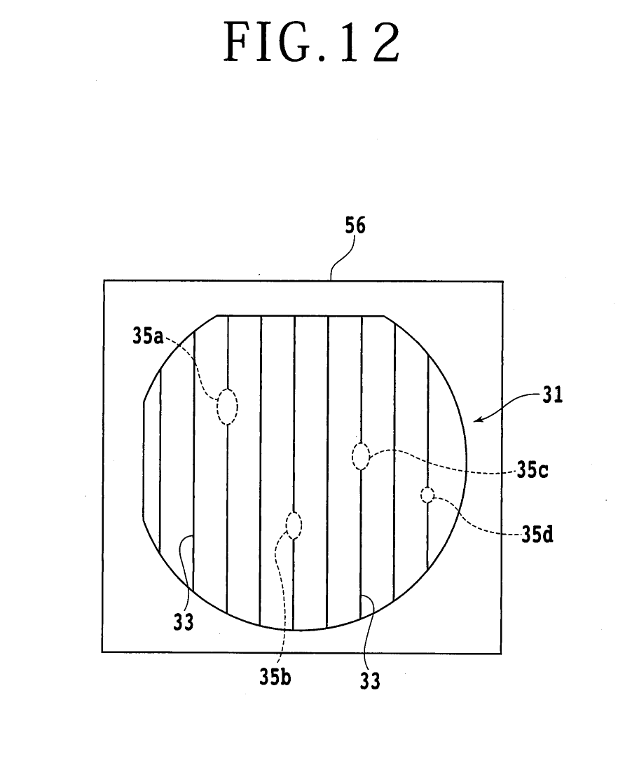

FIG. 12 shows another example of the projected image 31 in the case that some of the modified layers 23 have not been properly formed inside the ingot 11. In the case that some of the modified layers 23 have not been properly formed inside the ingot 11, defective areas 35a, 35b, 35c, and 35d are present in the projected image 31 as shown in FIG. 12, in which the width of each dark portion 33 in all the defective areas 35a to 35d is less than the reference value. When at least one of these defective areas 35a to 35d is detected in the projected image 31, the separation start point forming step is performed again to properly form the modified layers 23 in the defective areas 35a to 35d. Alternatively, the processing conditions in the separation start point forming step may be changed so that subsequent faulty processing can be prevented.

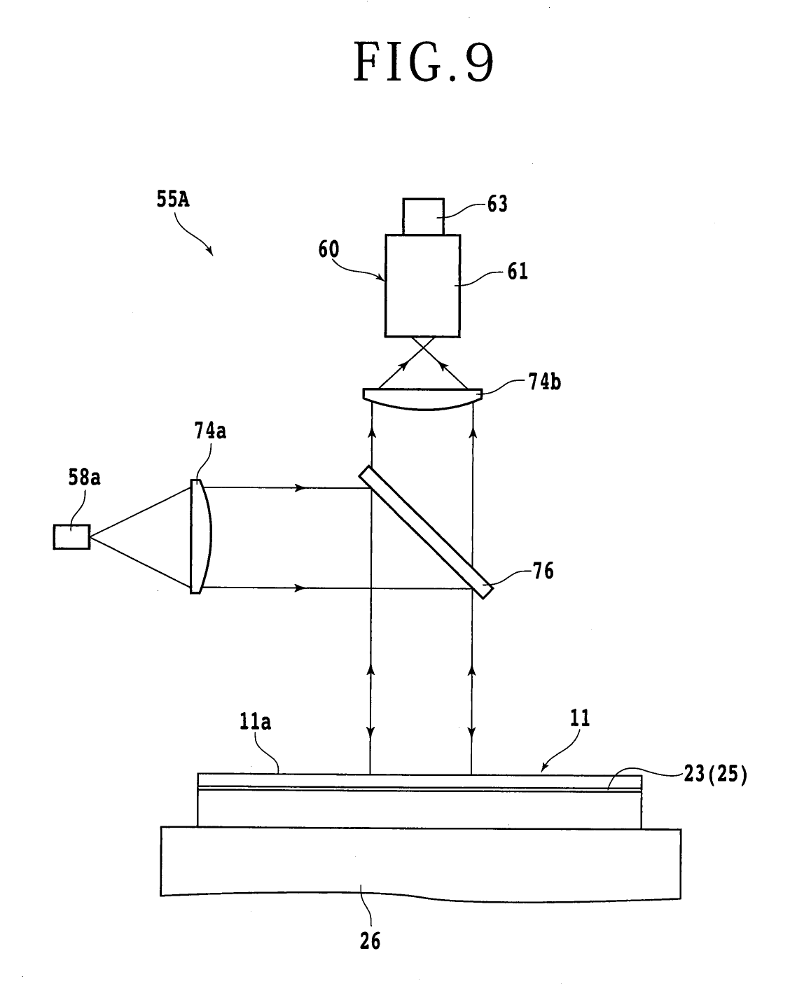

In the preferred embodiment shown in FIG. 8, a projected image is formed on the screen 56 and this projected image is next detected by the imaging unit 60 to form a detected image. However, in performing the inspecting method of the present invention, the screen 56 is not essential. An inspecting apparatus 55A not using the screen 56 according to another preferred embodiment of the present invention will now be described with reference to FIG. 9. In the inspecting apparatus 55A shown in FIG. 9, light is perpendicularly applied to the upper surface 11a of the ingot 11 held on the holding table 26. That is, the light impinges on the upper surface 11a at right angles thereto, i.e., at an incidence angle of 0 degrees (i.e., the optical path of the incident light is parallel to the normal to the upper surface 11a). Further, an imaging unit 60 is located so as to be opposed to the upper surface 11a of the ingot 11. The incident light on the upper surface 11a is reflected at right angles to the upper surface 11a to reach the imaging unit 60 located above the upper surface 11a. Accordingly, a detected image with no distortion can be obtained.

As shown in FIG. 9, the inspecting apparatus 55A includes a light source 58a, a beam splitter 76, and the imaging unit 60. Light emitted from the light source 58a is converted into parallel light by a lens 74a. The parallel light emerging from the lens 74a enters the beam splitter 76. The light thus entering the beam splitter 76 is partially reflected by the beam splitter 76 toward the upper surface 11a of the ingot 11. The light thus reflected by the beam splitter 76 impinges on the upper surface 11a at right angles thereto and is then reflected on the upper surface 11a toward the beam splitter 76. The reflected light from the upper surface 11a is partially transmitted through the beam splitter 76 and next focused by a lens 74b to the imaging unit 60. The imaging unit 60 includes a lens 61 and an imaging device 63. The light focused to the imaging unit 60 is imaged on the imaging device 63 by the lens 61 to form a detected image.

Although not shown in FIG. 9, the determining unit 62 shown in FIG. 8 is connected to the imaging device 63. This determining unit 62 compares the detected image obtained by the imaging device 63 with the preset conditions to determine whether or not the modified layers 23 and the cracks 25 have been properly formed inside the ingot 11. By using the inspecting apparatus 55A, the distortion in the detected image to be obtained by the imaging unit 60 can be greatly reduced. Accordingly, it is possible to more accurately evaluate the condition of asperities generated on the upper surface 11a of the ingot 11 due to the formation of the separation start point composed of the modified layers 23 and the cracks 25 inside the ingot 11.

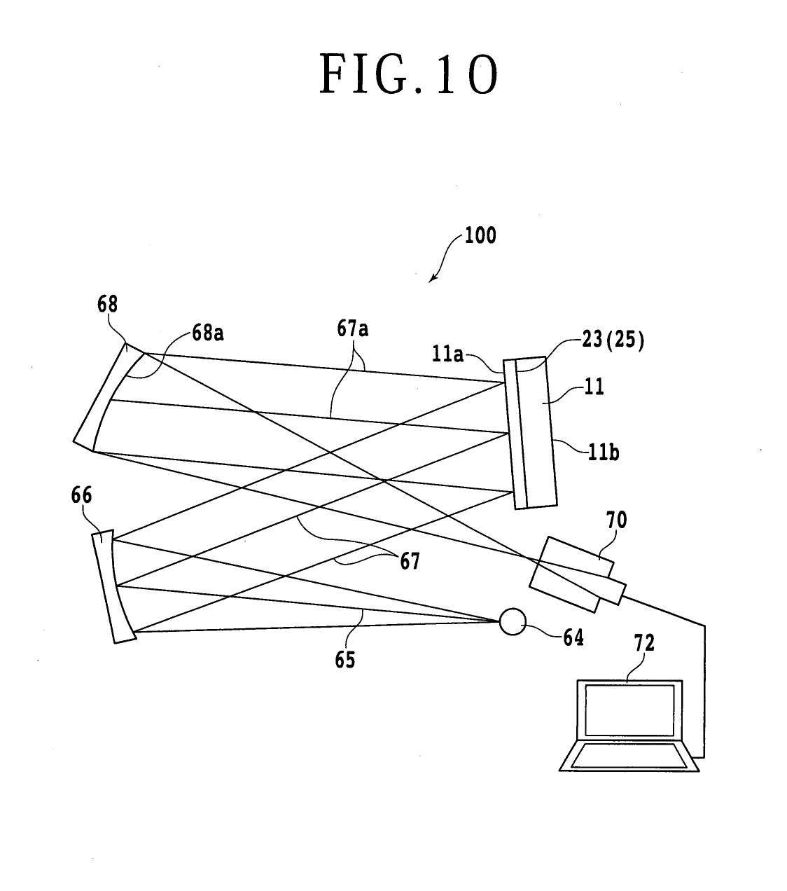

Referring to FIG. 10, there is shown an inspecting apparatus 100 according to still another preferred embodiment of the present invention. The inspecting apparatus 100 shown in FIG. 10 includes a holding table (support table) 26 (not shown in FIG. 10) for holding the ingot 11 in the condition where the upper surface 11a is exposed, a point light source 64 for emitting light 65, a first concave mirror 66 for reflecting the light 65 emitted from the point light source 64 to convert the light 65 into parallel light 67, and a second concave mirror 68 for reflecting reflected light 67a from the upper surface 11a of the ingot 11 so as to focus it, the reflected light 67a being obtained by the reflection of the parallel light 67 on the upper surface 11a.

The inspecting apparatus 100 further includes a camera 70 located at a position where a projected image formed on a projection surface (concave surface) 68a of the second concave mirror 68 is focused and a personal computer 72 having a memory for storing preset conditions and a detected image obtained by the camera 70.

According to the inspecting apparatus 100 shown in FIG. 10, the concave surface 68a of the second concave mirror 68 functions as a projection surface for forming a projected image. The light focused by the projection surface 68a enters the camera 70. Accordingly, the projected image formed on the projection surface 68a is detected by the camera 70, so that a very bright detected image can be obtained. As a modification, the second concave mirror 68 may be replaced by a simple screen located at the position of the second concave mirror 68. In this case, a detected image obtained by the camera 70 is dark and insufficient in contrast. However, by using a highly sensitive camera with low noise, a projected image formed on the screen can be sufficiently detected.

In the above description, the inspecting method of the present invention is applied to a hexagonal single crystal ingot in which the separation start point composed of the modified layers 23 and the cracks 25 is previously formed. However, the applicability of the inspecting method of the present invention is not limited to such a hexagonal single crystal ingot. For example, the inspecting method of the present invention is also applicable to a semiconductor ingot such as a silicon ingot and a compound semiconductor ingot, in which a separation start point composed of modified layers and cracks is previously formed. Also in this case, it is similarly determined whether or not the modified layers have been properly formed inside the semiconductor ingot.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A semiconductor ingot inspecting method comprising:
a separation start point forming step of setting the focal point of a laser beam having a transmission wavelength to a semiconductor ingot inside said ingot at a predetermined depth from an upper surface of said ingot, said predetermined depth corresponding to the thickness of a wafer to be produced from said ingot, and next applying said laser beam to said upper surface of said ingot as relatively moving said focal point and said ingot to thereby form modified layers parallel to said upper surface of said ingot and cracks extending from each modified layer, thus forming a separation start point composed of said modified layers and said cracks;
a light applying step of applying light from a light source to said upper surface of said ingot after performing said separation start point forming step, said light impinging on said upper surface of said ingot at a predetermined incidence angle;
a projected image forming step of reflecting said light on said upper surface of said ingot to obtain reflected light after performing said light applying step, and then forming a projected image from said reflected light, said projected image showing the emphasis of asperities generated on said upper surface of said ingot due to the formation of said modified layers and said cracks inside said ingot;
an imaging step of detecting said projected image to form a detected image after performing said projected image forming step; and
a determining step of comparing said detected image with preset conditions to determine the condition of said modified layers and said cracks after performing said imaging step.

2. A hexagonal single crystal ingot inspecting method comprising:
a preparing step of preparing a hexagonal single crystal ingot having a first surface, a second surface opposite to said first surface, a c-axis extending from said first surface to said second surface, and a c-plane perpendicular to said c-axis;
a separation start point forming step of setting the focal point of a laser beam having a transmission wavelength to said ingot inside said ingot at a predetermined depth from said first surface of said ingot after performing said preparing step, said predetermined depth corresponding to the thickness of a wafer to be produced from said ingot, and next applying said laser beam to said first surface of said ingot as relatively moving said focal point and said ingot to thereby form modified layers parallel to said first surface of said ingot and cracks extending from each modified layer along said c-plane, thus forming a separation start point composed of said modified layers and said cracks;
a light applying step of applying light from a light source to said first surface of said ingot after performing said separation start point forming step, said light impinging on said first surface of said ingot at a predetermined incidence angle;
a projected image forming step of reflecting said light on said first surface of said ingot to obtain reflected light after performing said light applying step, and then forming a projected image from said reflected light, said projected image showing the emphasis of asperities generated on said first surface of said ingot due to the formation of said modified layers and said cracks inside said ingot;
an imaging step of detecting said projected image to form a detected image after performing said projected image forming step; and
a determining step of comparing said detected image with preset conditions to determine the condition of said modified layers and said cracks after performing said imaging step.

3. The hexagonal single crystal ingot inspecting method according to claim 2, wherein said hexagonal single crystal ingot is selected from an SiC single crystal ingot and a GaN single crystal ingot.

4. An inspecting apparatus for inspecting a hexagonal single crystal ingot having a first surface, a second surface opposite to said first surface, a c-axis extending from said first surface to said second surface, and a c-plane perpendicular to said c-axis, said ingot being previously processed by applying a laser beam having a transmission wavelength to said ingot, to said first surface of said ingot to thereby form modified layers inside said ingot and cracks extending from each modified layer along said c-plane, thus forming a separation start point composed of said modified layers and said cracks, whereby asperities corresponding to said modified layers and said cracks are generated on said first surface of said ingot, said inspecting apparatus comprising:
a holding table for holding said ingot in the condition where said first surface of said ingot is exposed;
a light source for applying light to said first surface of said ingot held on said holding table, said light impinging on said first surface of said ingot at a predetermined incidence angle;
imaging means for detecting a projected image to form a detected image, said projected image being formed by reflecting said light on said first surface of said ingot at a reflection angle corresponding to said predetermined incidence angle, said projected image showing the emphasis of said asperities generated on said first surface of said ingot due to the formation of said separation start point inside said ingot; and
determining means for comparing said detected image with preset conditions to determine the condition of said modified layers and said cracks.

5. An inspecting apparatus for inspecting a hexagonal single crystal ingot having a first surface, a second surface opposite to said first surface, a c-axis extending from said first surface to said second surface, and a c-plane perpendicular to said c-axis, said ingot being previously processed by applying a laser beam having a transmission wavelength to said ingot, to said first surface of said ingot to thereby form modified layers inside said ingot and cracks extending from each modified layer along said c-plane, thus forming a separation start point composed of said modified layers and said cracks, whereby asperities corresponding to said modified layers and said cracks are generated on said first surface of said ingot, said inspecting apparatus comprising:
a holding table for holding said ingot in the condition where said first surface of said ingot is exposed;
a point light source for emitting light;
a first concave mirror for reflecting said light emitted from said point light source to convert said light into parallel light and then applying said parallel light to said first surface of said ingot, said parallel light impinging on said first surface of said ingot at a predetermined incidence angle;
a second concave mirror having a projection surface for forming a projected image, said projected image being formed by reflecting said parallel light on said first surface of said ingot at a reflection angle corresponding to said predetermined incidence angle, said projected image showing the emphasis of said asperities generated on said first surface of said ingot due to the formation of said separation start point inside said ingot;
imaging means for detecting said projected image formed on said projection surface of said second concave mirror to thereby form a detected image; and
determining means for comparing said detected image with preset conditions to determine the condition of said modified layers and said cracks.

6. A laser processing apparatus comprising:
a chuck table for holding a hexagonal single crystal ingot having a first surface, a second surface opposite to said first surface, a c-axis extending from said first surface to said second surface, and a c-plane perpendicular to said c-axis;
laser beam applying means for applying a laser beam having a transmission wavelength to said ingot, to said first surface of said ingot held on said chuck table to thereby form modified layers inside said ingot and cracks extending from each modified layer along said c-plane, thus forming a separation start point composed of said modified layers and said cracks, whereby asperities corresponding to said modified layers and said cracks are generated on said first surface of said ingot;
a light source for applying light to said first surface of said ingot held on said chuck table, said light impinging on said first surface of said ingot at a predetermined incidence angle;
imaging means for detecting a projected image to form a detected image, said projected image being formed by reflecting said light on said first surface of said ingot at a reflection angle corresponding to said predetermined incidence angle, said projected image showing the emphasis of said asperities generated on said first surface of said ingot due to the formation of said separation start point inside said ingot;
determining means for comparing said detected image with preset conditions to determine the condition of said modified layers and said cracks; and
control means for essentially controlling said laser beam applying means, said imaging means, and said determining means.
